(19) United States
(12) Patent Application Publication
(10) Pub. No.: US 2025/0154644 A1
(43) Pub. Date: May 15, 2025

(54) HIGH PRESSURE INERT OXIDATION AND IN-SITU ANNEALING PROCESS TO IMPROVE FILM SEAM QUALITY AND WER

(71) Applicant: Lam Research Corporation, Fremont, CA (US)

(72) Inventors: Eli Jeon, Sherwood, OR (US); Douglas Walter Agnew, Portland, OR (US); Shiva Sharan Bhandari, Sherwood, OR (US); Ian John Curtin, Portland, OR (US); Joseph R. Abel, West Linn, OR (US); Jason Alexander Varnell, Tigard, OR (US); Cody Barnett, Beaverton, OR (US); Christopher Nicholas Iadanza, Tualatin, OR (US); Dustin Zachary Austin, Tigard, OR (US)

(21) Appl. No.: 18/838,576

(22) PCT Filed: Feb. 14, 2023
(86) PCT No.: PCT/US2023/062571

§ 371 Date: Aug. 14, 2024

Related U.S. Application Data
(60) Provisional application No. 63/365,475, filed on May 27, 2022.
(60) Provisional application No. 63/268,057, filed on Feb. 15, 2022.

(51) Int. Cl. C23C 16/04; C23C 16/40; C23C 16/455; H01J 37/32; H01L 21/02

(52) U.S. Cl. CPC C23C 16/045; C23C 16/401; C23C 16/45536; C23C 16/45544; H01J 37/32449; H01L 21/02164; H01L 21/02274; H01L 21/0228

(57) ABSTRACT

Methods of filling a gap with a dielectric material including using an inhibition plasma during deposition. The inhibition plasma increases a nucleation barrier of the deposited film. The inhibition plasma selectively interacts near the top of the feature, inhibiting deposition at the top of the feature compared to the bottom of the feature, enhancing bottom-up fill. A process chamber may have multiple pressure switches to enable a process after deposition at a higher pressure than the pressure during deposition.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Many semiconductor device fabrication processes involve formation of films including silicon-containing films such as silicon oxide or silicon nitride. Plasma enhanced atomic layer deposition (ALD) may be used to deposit silicon-containing films. Depositing a high-quality film can be particularly challenging when depositing films in gaps. Challenges can include the formation of voids and/or seams in the films.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are methods and systems of depositing films. In one aspect of the embodiments herein, a method is provided, including: providing a substrate having a structure with a gap in a process chamber; and performing a first set of one or more cycles of: exposing the substrate to a plasma including an inhibition gas to inhibit deposition on a portion of the gap; and after (a), depositing dielectric material in the gap; and after performing the first set of one or more cycles, depositing additional dielectric material in the gap, wherein a pressure of the process chamber is at least 8 Torr during (a) and (b).

In some embodiments, the pressure of the process chamber is between about 8 Torr and about 30 Torr during (a) and (b). In some embodiments, the pressure of the process chamber is between about 8 Torr and about 100 Torr during (a) and (b). In some embodiments, the pressure of the process chamber during (b) is different from the pressure of the process chamber during (a). In some embodiments, the pressure of the process chamber during (b) is the same as the pressure of the process chamber during (a). In some embodiments, depositing dielectric material during (b) is performed using an atomic layer deposition (ALD) process. In some embodiments, the ALD process is a plasma enhanced ALD process. In some embodiments, further including, before (a), depositing a conformal liner film in the gap using an ALD process.

In some embodiments, the inhibition gas is a halogen-containing gas. In some embodiments, the inhibition gas is a nitrogen-containing gas. In some embodiments, a temperature of the process chamber is between about 200° C., and about 800° C., during (a) and (b). In some embodiments, the plasma has a high-frequency component power between about 250 W and about 1500 W per substrate. In some embodiments, the plasma has a low-frequency component power between about 250 W and about 1250 W per substrate. In some embodiments, the dielectric material is silicon-containing material. In some embodiments, the dielectric material is silicon oxide.

In another aspect of the embodiments herein, a system is disclosed, including: a process chamber; a first valve that controls flow of a first process gas into the process chamber; a second valve that controls flow of a second process gas into the process chamber; a controller configured to: determine a pressure of the process chamber exceeds a first threshold; and cause the first valve to divert flow of the first process gas to not flow into the process chamber, wherein the second valve remains configured to flow the second process gas into the process chamber.

In some embodiments, the system further includes a first pressure switch, wherein the first pressure switch is configured to automatically divert the first process gas when the process chamber exceeds the first threshold. In some embodiments, the system further includes a second pressure switch, wherein the second pressure switch is configured to automatically divert the second process gas when the process chamber exceeds a second threshold, wherein the second threshold is higher than the first threshold. In some embodiments, the first threshold is about 30 Torr. In some embodiments, the controller is further configured to determine a pressure of the process chamber exceeds a second threshold higher than the first threshold and, based on the determination that the pressure exceeds the second threshold, cause the second valve to divert flow of the second process gas to not flow into the process chamber. In some embodiments, the second threshold is about 550 Torr. In some embodiments, the first process gas includes a hazardous production material. In some embodiments, the first process gas includes a silicon-containing precursor. In some embodiments, the second process gas includes an inert gas.

These and other features of the disclosed embodiments will be described in detail below with reference to the associated drawings.

### BRIEF DESCRIPTION OF DRAWINGS

FIG. 1 presents a flow diagram of operations for one example embodiment.

FIG. 2A and 2B presents an illustration of example embodiments to fill gaps.

FIG. 3 presents a flow diagram of operations for one example embodiment.

FIG. 4 presents a flow diagram of operations for atomic layer deposition processes.

FIG. 5A presents an illustration of pressure switches to operate process chambers at a higher pressure.

FIG. 5B presents a flow diagram of operations for one example embodiment.

FIGS. 6-9 are schematic diagrams of examples of process chambers for performing methods in accordance with disclosed embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often include dielectric gap fill using chemical vapor deposition (CVD) and/or atomic layer deposition (ALD) methods to fill features. Described herein are methods of filling features with dielectric material including but not limited to silicon-containing films such as silicon oxide, silicon nitride, silicon carbide, etc., and related systems and apparatuses. The methods described herein can be used to fill vertically oriented features formed in a substrate. Such features may be referred to as gaps, recessed features, negative features, unfilled features, or simply features. Filling such features may be referred to as gap fill. Features formed in a substrate can be characterized by one or more of narrow and/or re-entrant openings, constrictions within the feature, and high aspect ratios. In some implementations, a feature may have an aspect ratio of at least about 2:1, at least about 4:1, at least about 6:1, at least about 20:1, at least about 100:1, or greater. The substrate may be a silicon wafer, e.g., a 200-mm wafer, a 300-mm wafer, or a 450-mm wafer, including wafers having one or more layers of material such as dielectric, conducting, or semi-conducting material deposited thereon.

One aspect of the disclosure relates to a method of using an inhibition plasma during atomic layer deposition (ALD) of dielectric material in gaps that facilitates void-free bottom gap fill at high pressure. The inhibition plasma creates a passivated surface and increases a nucleation barrier of the deposited ALD film When the inhibition plasma interacts with material in the feature, the material at the bottom of the feature receives less plasma treatment than material located closer to a top portion of the feature or in field because of geometrical shadowing effects. As a result, deposition at the top of the feature is selectively inhibited and deposition in lower portions of the feature proceeds with less inhibition or without being inhibited. As a result, bottom-up fill is enhanced, which creates a more favorable sloped profile that mitigates the seam effect and inhibits void formation. Halogen-containing plasmas can be effective inhibition plasmas. For example, for some applications, a plasma generated from nitrogen trifluoride (NF₃) may provide an inhibition effect in a substantially reduced time compared to a plasma generated from molecular nitrogen (N₂). Described herein are methods of filling features with reduced void size and/or formation.

High pressure may refer to a pressure greater than about 8 Torr, greater than about 10 Torr, between about 10 Torr and about 30 Torr, or between about 10 Torr and about 100 Torr. Generally, deposition rate increases with increasing pressure. However, previously the inhibition plasma treatment was performed at a lower pressure than an ALD process to deposit dielectric material. Changing the pressure of the process chamber between ALD cycles and inhibition plasma treatments requires significant time, which decreases throughput. Thus, present embodiments allow for the ALD process and inhibition plasma to be performed at the same pressure, or both at different high pressures, as noted above, decreasing the time spent changing chamber pressure and increasing throughput as well as film deposition rate per cycle. High pressure inhibition plasma treatments may also improve throughput as higher pressure increases the inhibition depth for a given treatment, reducing the time required for an inhibition treatment to inhibit a feature, particularly high aspect ratio features that may have an aspect ratio of about 100:1 or more or about 180:1 or more.

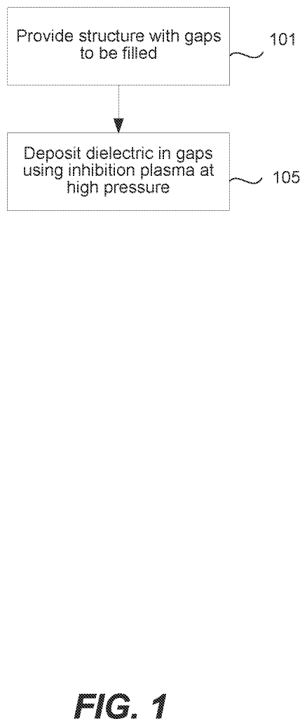

FIG. 1 is a process flow diagram that illustrates a method of filling gaps with dielectric material. The method begins with providing a structure with one or more gaps to be filled in operation 101. The structure may be formed by one or more layers of material deposited on a substrate. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to for gap fill of gaps of other substrates, such as glass, plastic, and the like, including in the fabrication of microelectromechanical (MEMS) devices.

Examples of structures include 3D NAND structures, DRAM structures, field effect transistor (FET) structures, and shallow trench isolation (STI) structures. The structures include gaps with the sidewalls of the gaps formed by a material susceptible to etch and/or having different selectivity for underlying layers. In one example, 3D NAND structure includes oxide-nitride-oxide-nitride (ONON) stacks covered with a poly silicon (poly Si) layer. As the oxide and nitride layers may have different selectivity for depositing the poly Si layer, the poly Si layer may deposit at different rates on each layer, resulting in a roughness that is undesirable and leads to voids in filled feature. Other examples of sidewall materials include oxides, metals, and semiconducting materials. The methods described herein are not limited to a particular class of sidewall material.

Dielectric material is deposited in the gaps using an inhibition plasma in operation 105. As discussed further below, this can involve cycles of inhibition plasma followed by ALD of the dielectric film. In some embodiments, the gaps may be filled by a process involving cycles of inhibition plasma followed by ALD of the dielectric material.

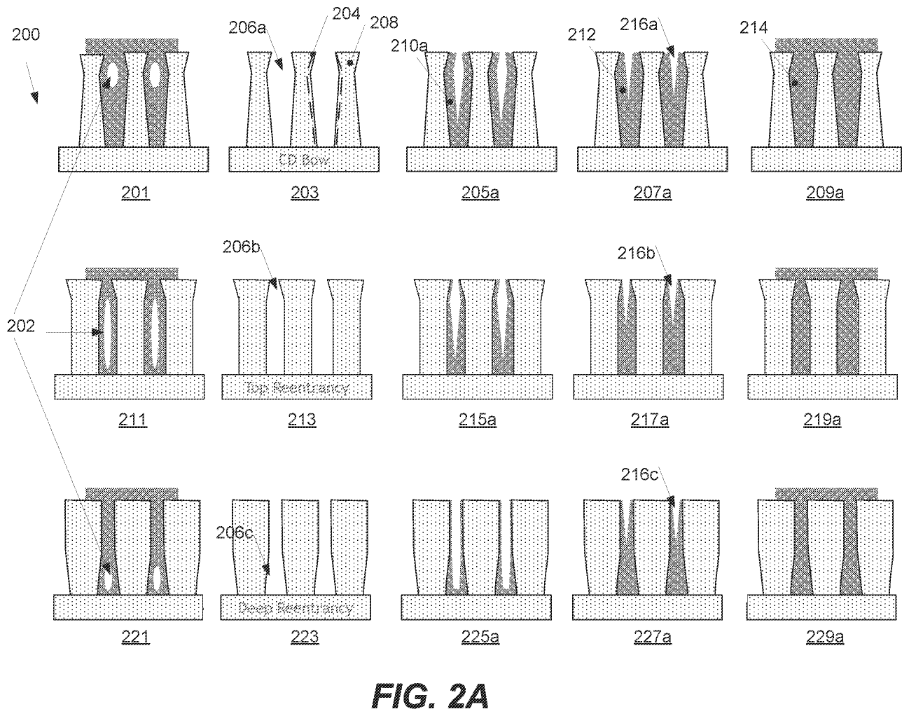

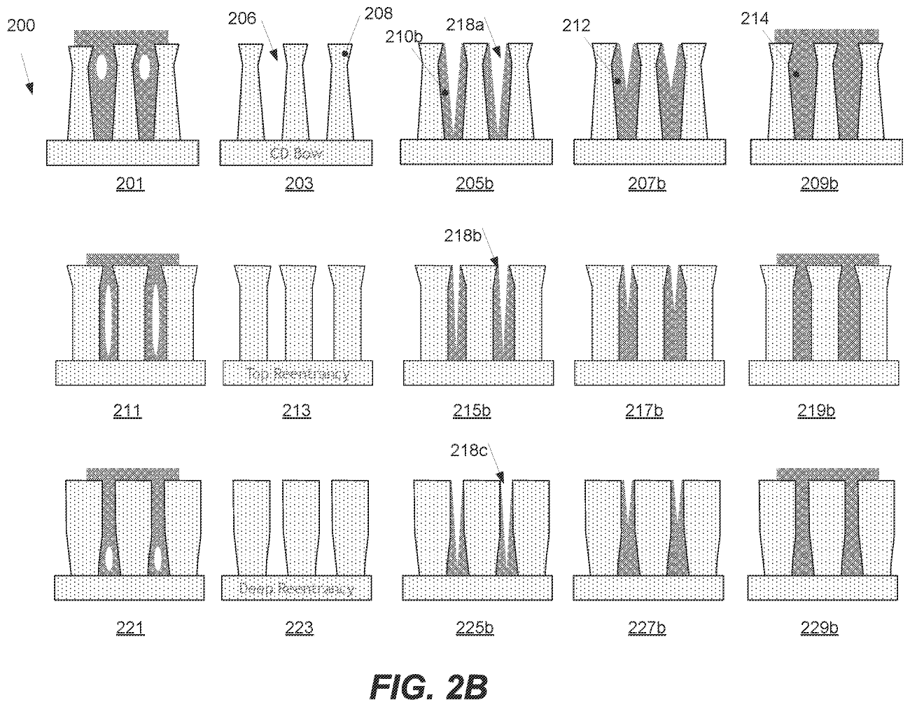

FIGS. 2A and 2B show examples of structures 200 having various types of features during various stages of a gap fill method described herein. Structures 203, 213, and 223 provide features 206a-c to be filled with dielectric material. Structure 203 has a critical dimension (CD) bow feature 206a. Structure 213 has a top reentrancy feature 206b, and structure 223 has a deep reentrancy feature 206c. The structures may comprise a layer 208 upon which dielectric material is to be deposited. In some embodiments, layer 208 may be a poly Si layer or any other suitable layer. In some embodiments, layer 208 is a conformal layer deposited on top of an underlying layer (not shown), such ONON stacks covered with a poly Si layer, which forms sidewalls 204 of the gaps 206a-c (shown once in structure 203).

Structures 201, 211, and 221 illustrate gaps filled without using an inhibition plasma during ALD. Each of structures 201, 211, and 221 have voids 202. These voids may form as a result of conformal deposition, as the top of the features pinch off before deeper portions of the feature are filled with dielectric material. Structures 205a-209a, 215a-219a, and 225a-229a illustrate filling structures with dielectric material using an inhibition plasma. Structures 205a, 215a, and 225a are filled with a dielectric material 210a using a conformal process, such as an ALD process without an inhibition treatment. As an ALD process with an inhibition treatment may proceed slower than an ALD process without an inhibition treatment, it may be preferable to initially deposit dielectric material using an ALD process without an inhibition treatment.

Structures 207a, 217a, and 227a illustrate gaps filled using an ALD process with an inhibition treatment. As the inhibition treatment substantially reduces deposition near the top of the feature, dielectric material 212 may form gaps 216a-c that have a tapered profile from the top of the gap to the bottom of the gap.

Structures 209a, 219a, and 229a illustrate gaps that are filled with dielectric material 214. As the gaps are filled using a bottom-up mechanism facilitated by an inhibition plasma, the aspect ratio of the features may decrease until an inhibition treatment is not necessary to achieve void-free gap fill. Thus, structures 209a, 219a, and 229a may be filled using an ALD process without an inhibition treatment or an alternative deposition techniques, such as chemical vapor deposition.

FIG. 2B presents the same initial structures 203, 213, and 223 as shown in FIG. 2A. However, the gap fill process shown in FIG. 2B starts with an inhibition plasma treatment process for initial gapfill. As shown in structures 205b, 215b, and 225b, dielectric material 210b is deposited in the features and gaps 218a-c have a tapered profile resulting from inhibited deposition near the top of the feature compared to the bottom of the feature. Structures 207b, 217b, and 227b illustrate additional cycles of ALD with an inhibition plasma treatment, where additional dielectric material 210b has been deposited in the features. Structures 209b, 219b, and 229b may be similarly filled using ALD or CVD processes as described above.

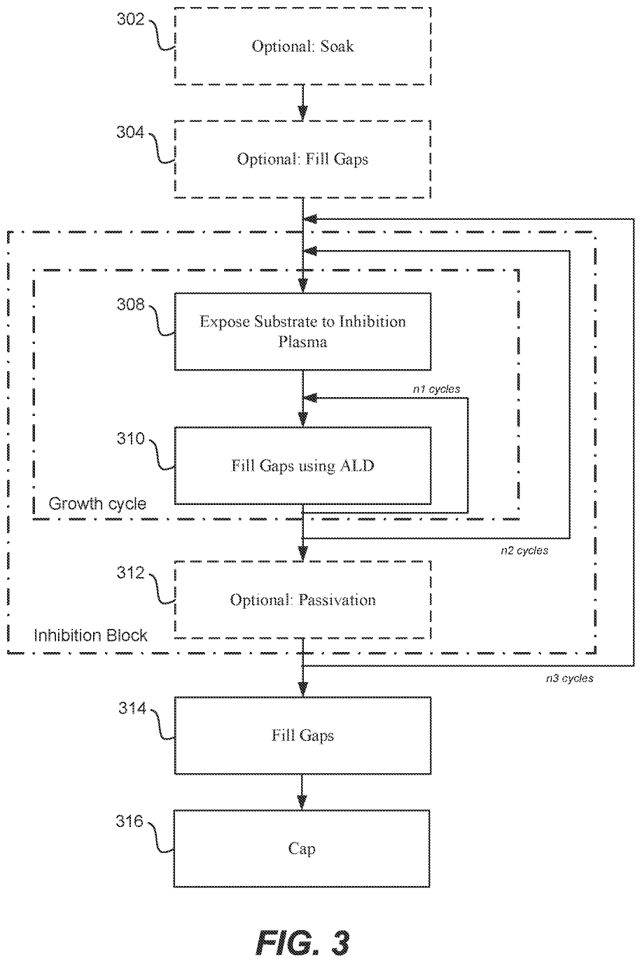

FIG. 3 shows an example of a process sequence that may be used in accordance with the disclosed embodiments. Some operations (e.g., soak 302, passivation 312) may be omitted in certain embodiments and operations may be added in certain embodiments. In the example process sequence of FIG. 3, one or more features on a substrate undergo gap fill. In some embodiments, one or more operations described in FIG. 3 may be performed in a single process chamber or tool. The process may begin with a soak operation 203 of the substrate after being provided to a deposition chamber as represented in operation 302. This can be useful, for example, to remove particles or other pretreatment. Then, a dielectric material is optionally deposited in gaps of the substrate as represented in operation 304. The dielectric material may be deposited by any conformal process, including ALD, CVD, or sputtering, including any plasma enhanced processes. Further details of ALD are discussed below. In some embodiments, operation 304 is not performed and deposition may begin as part of an inhibition block. In some embodiments, n3 inhibition blocks are performed, with the operations of an inhibition block shown. The inhibition plasma is a surface treatment as represented in operation 308. As discussed above, the plasma may include halogen species including anion and radical species such as F⁻, Cl⁻, I⁻, Br⁻, fluorine radicals, etc. In some embodiments, the plasma is generated from an inhibition gas that comprises halogen-containing gases. In some examples, the halogen-containing gases can include but not limited to nitrogen trifluoride (NF₃). Other inhibition gas plasmas may be used. For example, plasmas generated from molecular nitrogen (N₂), molecular hydrogen (H₂), ammonia (NH₃), amines, diols, diamines, amino alcohols, thiols or combinations thereof may be used as inhibition plasmas. In some embodiments, the species flowed into the plasma are capable of etching the dielectric material to be deposited in the gaps in addition to inhibiting deposition.

When the inhibition plasma interacts with material in the feature, the material at the bottom of the feature receives less plasma treatment than material located closer to a top portion of the feature or in the field region because of geometrical shadowing effects. As a result, deposition at the top of the feature is selectively inhibited and deposition in lower portions of the feature proceeds with less inhibition or without being inhibited.

In FIG. 3, the next operation in the inhibition block is n1 cycles of ALD fill in operation 310. The dielectric material is deposited selectively at the bottom of the feature. The inhibition plasma in operation 308 and the n1 cycles of ALD fill in operation 310 together make a growth cycle, and can be repeated n2 times to continue filling the feature with intermittent inhibition operations when the inhibition effect diminishes. The number of growth cycles in an inhibition block may depend on the re-entrancy of the feature, i.e., if it narrows at one or more points from the bottom to the top of the feature. Features that exhibit more re-entrancy may use a longer inhibition time or multiple inhibition blocks. Alternatively, as discussed further below, a shorter inhibition time and fewer ALD cycles may be used to gradually fill features having re-entrancy. Once the reentrant feature is filled below the re-entrancy, the growth cycles and inhibition blocks may be adjusted to increase the speed of fill to improve throughput. In the example of FIG. 3, the inhibition block ends with an optional passivation operation as represented in operation 312. The passivation operation 312 is a surface treatment that removes residual inhibitor and can also densify the deposited film. In some embodiments, an oxygen plasma is used. In some embodiments, operation 312 may be omitted.

One or more additional inhibition blocks, including growth cycle and passivation, may be performed for a total of n3 inhibition blocks. The number of inhibition blocks depends on how much material is used to fill the feature. Inhibition plasma, ALD, and passivation conditions may be changed from inhibition block to inhibition block to fill the feature. For example, an inhibition plasma duration may be 30 seconds until the bottom quarter of the feature is filled (inhibition block 1), then changed to 10 seconds for the middle 50% of the structure (inhibition block 2), etc. In some embodiments, the duration of an inhibition plasma may be based on the aspect ratio and/or depth of the structure to be filled. In some implementations, the first inhibition block may have a longer inhibition plasma duration and a higher power in order to smooth sidewalls as described above compared to subsequent inhibition blocks. The duration of an inhibition plasma for any inhibition block described herein may be at least about 0.1 seconds, at least about 0.5 seconds, at least about 1 second, at least about 5 seconds, at least about 10 seconds, at least about 20 seconds, or at least about 30 seconds.

When the feature is nearly filled, inhibition may no longer be necessary, and the fill can be completed without using inhibition in an operation 314. In some embodiments, a cap or overburden layer of dielectric may then be deposited in an operation 316. Plasma enhanced chemical vapor deposition (PECVD) may be used at this stage for a fast deposition.

In various embodiments, the inhibition plasma is an in-situ plasma, such that the plasma is formed directly above the substrate surface in the station. In some embodiments the plasma is a capacitively coupled plasma (CCP). In some embodiments, the plasma may be a dual-frequency plasma having a low-frequency component and a high-frequency component. Example power for a 4-station chamber for an in-situ plasma may be at least about 1000 W, at least about 2500 W, between about 1000 W and about 6000 W, between about 1000 W and about 3000 W, and between about 2500 W and about 6000 W. Higher power may increase an etching component of the plasma. Example power for a 4-station chamber for an in-situ plasma may be at least about 2500 W, between about 1000 W and about 6000 W, between about 1000 W and about 3000 W, and between about 2500 W and about 6000 W. In some embodiments, lower power, e.g., 2500 W, may be used with a longer duration of plasma treatment, e.g., 30 seconds, to etch the substrate. These powers are for a chamber processing four 300 mm wafers; appropriate modification may be made for larger/smaller wafers and/or more/less chambers (e.g., these values may be divided by 4 for a single wafer, such that 1000 W for a four wafer chamber may be about 250 W for a single wafer or about 0.3536 W/cm² per substrate area). In some embodiments, these powers may be for a single-frequency plasma. In some embodiments, these powers may be for a dual-frequency plasma, where the power for a low-frequency component may be different from the power for a high-frequency component. Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that second reactant is ignited in a remote plasma generator upstream of the station, then delivered to the station where the substrate is housed.

In some embodiments the ratio of inhibition species to inert gas may be about 1:5, about 1:10 or between about 1:10 and about 1:20, or between about 1:5 and about 1:5000. Generally, increasing the proportion of the gas flow that is the inhibiting species, such as NF₃, increases the inhibition effect of exposing the substrate to an inhibition plasma.

In some embodiments, pressure of the process chamber during ALD and inhibition plasma treatments may be greater than about 8 Torr, greater than about 10 Torr, between about 10 Torr and about 30 Torr, or between about 10 Torr and about 100 Torr.

In some embodiments, temperature of the process chamber during ALD and inhibition plasma treatment may be between about 200° C., and about 800° C., between about 300° C., and about 700° C., or at least about 200° C.

In some embodiments, flow of the inhibition species may be between about 0 and about 6000 sccm.

As discussed above, ALD is used to fill the features. ALD is a technique that sequentially deposits thin layers of material. ALD processes use surface-mediated deposition reactions to deposit films on a layer-by-layer basis in cycles. The concept of an ALD “cycle” is relevant to the discussion of various embodiments herein. Generally, a cycle is the minimum set of operations used to perform a surface deposition reaction one time. The result of one cycle is the production of at least a partial silicon-containing film layer on a substrate surface. Typically, an ALD cycle includes operations to deliver and adsorb at least one reactant to the substrate surface, and then react the adsorbed reactant with one or more reactants to form the partial layer of film. The cycle may include certain ancillary operations such as sweeping one of the reactants or byproducts and/or treating the partial film as deposited. Generally, a cycle contains one instance of a unique sequence of operations.

As an example, an ALD cycle may include the following operations: (i) delivery/adsorption of a precursor, (ii) purging of the precursor from the chamber, (iii) delivery of a second reactant and optional plasma ignition, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface-active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed species of the first precursor. When a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas or nitrogen-containing gas, is introduced to the chamber so that some of these molecules react with the first precursor adsorbed on the surface. In some processes, the second reactant reacts immediately with the adsorbed first precursor. In other embodiments, the second reactant reacts only if a source of activation such as plasma is applied temporally. The chamber may then be evacuated again to remove unbound second reactant molecules. As described above, in some embodiments the chamber may not be completely evacuated. Additional ALD cycles may be used to build film thickness.

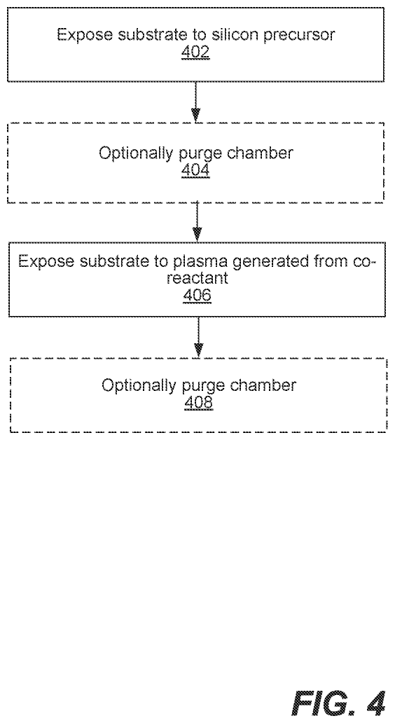

FIG. 4 presents a process flow diagram for a single plasma enhanced ALD cycle that may be implemented as part of operation 103 to deposit a conformal layer or for any of the other ALD operations shown in FIG. 3. In an operation 402, the substrate is exposed to a silicon-containing precursor, to adsorb the precursor onto the surface of the feature. This operation may be self-limiting. In some embodiments, the precursor adsorbs to less than all the active sites on the surface of the feature. In an operation 404, the process chamber is optionally purged to remove any unadsorbed silicon-containing precursors. In an operation 406, the substrate is exposed to a plasma generated from a co-reactant. Examples include oxygen-containing species (such as, O₂ and/or N₂O) to form a silicon oxide layer, nitrogen-containing species (such as, N₂ or NH₃) to form a silicon nitride layer, etc. In operation 408, the process chamber is optionally purged to remove byproducts from the reaction between the silicon-containing precursor and the oxidant. Operations 402 through 408 repeated for a number of cycles to deposit the silicon-containing layer to a desired thickness in the feature.

It should be noted that the processes described herein are not limited to a particular reaction mechanism. Thus, the process described with respect to FIG. 3 includes all deposition processes that use sequential exposures to silicon-containing reactants and conversion plasmas, including those that are not strictly self-limiting. The process includes sequences in which one or more gases used to generate a plasma is continuously flowed throughout the process with intermittent plasma ignitions.

For depositing silicon oxide, one or more silicon-containing precursors may be used. In some examples, silicon-containing precursors can include silanes (e.g., SiH₄), polysilanes (H₃Si—(SiH₂)ₙ—SiH₃) where n≥1, organosilanes, halogenated silanes, aminosilanes, alkoxysilanes, and the like. Organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH); di-isopropylaminosilane (DIPAS), di-sec-butylaminosilane (DSBAS), SiH₂[N(CH₂CH₃)₂]₂ (BDEAS) and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some implementations silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R1, R2, R3 and R4 is hydrogen, unbranched alkyl, branched alkyl, saturated heterocyclic, unsaturated heterocyclic groups, or combinations thereof. In some embodiments, when at least one X or Y is NR³R⁴, R3 and R4, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1,1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-sec butylamino-1,1-dimethyl disiloxane, 1-N-methylethylamino-1,1-dimethyl disiloxane, 1-N methylpropylamino-1,1-dimethyl disiloxane 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino-disiloxane, 1-piperidino-disiloxane, 1-t-butylamino disiloxane, and 1-dimethylamino-1,1,5,5,5,-pentamethyl disiloxane.

Where a deposited film includes oxygen, an oxygen-containing reactant may be used. Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O₄), dinitrogen pentoxide (N₂O₅), carbon monoxide (CO), carbon dioxide (CO₂), sulfur oxide (SO), sulfur dioxide (SO₂), oxygen-containing hydrocarbons (CₓH_{y}O_{z}), water (H₂O), formaldehyde (CH₂O), carbonyl sulfide (COS), mixtures thereof, etc.

Where a deposited film includes nitrogen, a nitrogen-containing reactant may be used. A nitrogen-containing reactant contains at least one nitrogen, for example, nitrogen (N₂), ammonia (NH₃), hydrazine (N₂H₄), amines (e.g., amines bearing carbon) such as methylamine (CH₅N), dimethylamine ((CH₃)₂NH), ethylamine (C₂H₅NH₂), isopropylamine (C₃H₉N), t-butylamine (C₄H₁₁N), di-t-butylamine (C₈H₁₉N), cyclopropylamine (C₃H₅NH₂), sec-butylamine (C₄H₁₃N), cyclobutylamine (C₄H₇NH₂), isoamylamine (C₅H₁₃N), 2-methylbutan-2-amine (C₅H₁₃N), trimethylamine (C₃H₉N), diisopropylamine (C₆H₁₅N), diethylisopropylamine (C₇H₁₇N), di-t-butylhydrazine (C₈H₂₀N₂), as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants. Other examples include NₓO_{y} compounds such as nitrous oxide (N₂O), nitric oxide (NO), nitrogen dioxide (NO₂), dinitrogen trioxide (N₂O₃), dinitrogen tetroxide (N₂O₄) and/or dinitrogen pentoxide (N₂O₅).

Another aspect of this disclosure relates to a process chamber having multiple pressure switches. Pressure switches may act as a safety feature for a process chamber. Certain species or combinations of species may be hazardous production materials (HPM). HPMs may be considered hazardous for various reasons, including corrosiveness, combustibility, or flammability. For example, pyrophoric gases, such as silanes, may ignite spontaneously when exposed to ambient air. Higher pressure processes may increase the risk associated with HPMs, which is undesirable. A pressure switch may operate as a safety feature that stops or diverts HPM flow when the process chamber exceeds a particular pressure, inhibiting the HPM from reacting or leaking from the process chamber.

While a pressure switch may mitigate the risks associated with HPMs, in some embodiments a single pressure switch may limit the processes that may be used in the chamber based on the most dangerous species, even if such species are not flowed for a particular process. In particular, an anneal process for silicon-containing films may be performed in the presence of inert gas or small amounts of hydrogen and oxygen, which are less hazardous than, e.g., a silicon-containing species such as silanes or aminosilanes. Anneal processes may be performed to densify films and improve cross-linking by, e.g., removing hydrogen from the film and promoting silicon-oxygen bonds, for a silicon oxide film. Performing the anneal process in the presence of oxygen may further drive cross-linking and oxidize the film. Similar benefits may be found by including hydrogen in the process gas for some silicon-containing films, e.g., silicon nitride or silicon carbide films. Generally, performing the anneal at higher pressure leads to a lower wet etch rate for the resulting films, which is desirable. However, process chambers may be limited at the maximum operating pressure based on risks associated with HPM that may be flowed during deposition. HPMs are typically not flowed during an anneal process.

Typically, anneal processes may be performed in a furnace that may contain multiple wafers. However, these processes may be slow and less tunable compared to a single chamber or single tool process where a silicon-containing film may be deposited and annealed. Thus, to facilitate performing substrate anneal processes in a chamber where the silicon-containing film is deposited, a process chamber having two switches may be used, where a first switch is configured for when HPMs, such as silicon-containing precursors, are flowed, and a second switch is configured for when HPMs are not flowed. This may allow the process chamber to operate at a higher pressure for certain operations, such as an anneal operation, improving the quality of films and throughput.

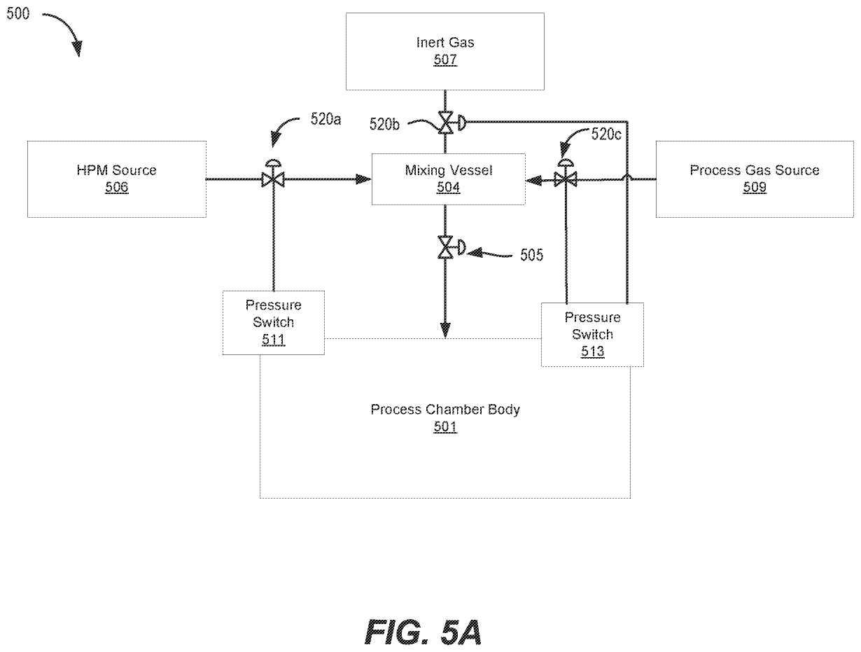

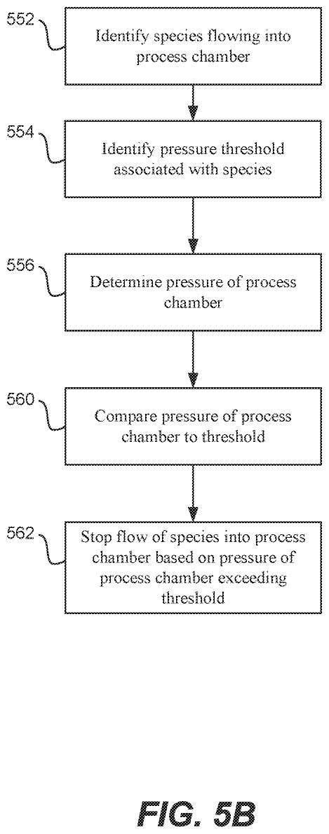

FIG. 5A presents an embodiment of a process station 500 that may be used to deposit material using a HPM at low pressure as well as process a substrate at high pressure without using an HPM. High pressure or high-pressure thresholds as described herein may be a pressure greater than about 30 Torr, greater than about 40 Torr, greater than about 60 Torr, between about 30 Torr and about 100 Torr, between about 30 Torr and about 50 Torr, less than about 500 Torr, less than about 550 Torr, or about 550 Torr. Low pressure or low-pressure thresholds as described herein may refer to a pressure less than about 30 Torr, less than about 40 Torr, or less than about 50 Torr. A process chamber body 501 fluidically communicates with a mixing vessel 506 via a showerhead inlet valve 505 that may control the introduction of process gases to the process chamber body. Mixing vessel 504 may blend and/or condition process gases. One or more mixing vessel inlet valves 520a-c may control introduction of process gases to mixing vessel 504. The mixing vessel inlet valves 520a-c may each be connected to a reactant source: mixing vessel inlet valve 520a is fluidically connected to a HPM source 506, mixing vessel inlet valve 520b is fluidically connected to an inert gas 507, and mixing vessel inlet valve 520c is fluidically connected to a process gas source 509. Process gas source 509 may deliver oxidizing species or hydrogen to the process chamber body, which may be less hazardous than, e.g., silane species.

Pressure switches 511 and 513 may be connected to the process chamber body 501 as well as one or more of mixing vessel inlet valve 520a-c. The pressure switches may be interlocked with one or more of mixing vessel inlet valve 520a-c to control whether the mixing vessel inlet valve may allow reactant to flow to the process chamber body. For example, pressure switch 511 may be interlocked with mixing vessel inlet valve 520a that controls flow of HPM. Thus, for mixing vessel inlet valve 520a to allow flow of HPM to the process chamber body, the pressure switch 511 must be enabled. This allows pressure switch 511 to safely close mixing vessel inlet valve 520a if the pressure of the process chamber body increases beyond a threshold pressure of pressure switch 511, which may be a low pressure switch that allows mixing vessel inlet valve 520a to flow HPM gas at low pressures. Conversely, pressure switch 513 may be interlocked with mixing vessel inlet valve 520b and 520c, allowing the mixing vessel inlet valve to flow inert gas or process gas when the process chamber body is at a high pressure. For example, pressure switch 513 may close mixing vessel inlet valve s 520b and 520c when the pressure exceeds the high pressure threshold, e.g., about 500 Torr or about 550 Torr. As may be understood, if mixing vessel inlet valve 520a is open, pressure switch 511 will trigger prior to pressure switch 513, as pressure switch 511 has a lower pressure threshold than pressure switch 513.

While two pressure switches are shown in FIG. 5A, it should be appreciated that more than two pressure switches may be used. In some embodiments, each mixing vessel inlet valve may be interlocked with a pressure switch, where the pressure threshold of the pressure switch is based on the species flowing through the inlet valve.

FIG. 5B presents a flowchart for using a pressure switch to control the flow of particular species according to various embodiments herein. Species flowing into a process chamber are identified in operation 552. In some embodiments, these species may include precursor species, such as silicon-containing reactants, as well as reactants such as oxygen-containing species, hydrogen, nitrogen-containing species, etc. A pressure threshold is identified that is associated with the species in operation 554. In some embodiments, the pressure threshold may be based on the species flowing into the process chamber that is the most hazardous or has the lowest associated pressure threshold. For example, if the species comprise a silane, the pressure threshold may be a low-pressure threshold as discussed above. In some embodiments, the pressure threshold may also be based on a flow rate of the species. For example, oxygen and hydrogen may be co-flowed with an inert gas during an anneal process. In some embodiments, a high-pressure threshold may be associated with oxygen and/or hydrogen species at a low total flow rate of hydrogen and oxygen species, e.g., a combined flow rate less than about 10 slm or less than about 20 slm. If the combined flow rate is greater than, e.g., about 10 slm or about 20 slm, a low-pressure threshold may be associated with the species. In some embodiments, if hydrogen or oxygen are mutually exclusively flowed, i.e., only one of hydrogen- and oxygen-containing species, a high-pressure threshold may be used.

A pressure of the process chamber is determined in operation 556. In some embodiments, the pressure may be determined by a pressure sensor that is operably connected to a controller, where the controller may be operably connected to inlet valves that flow species into the process chamber. In some embodiments, the pressure may be determined using a pressure switch that mechanically or automatically closes or diverts an operably connected mixing vessel inlet valve if the pressure is above a threshold associated with the species flowed via one or more interlocked mixing vessel inlet valves. The pressure of the process chamber may be compared to the threshold associated with the species flowing to the process chamber in operation 560. When the pressure of the process chamber exceeds the threshold, the flow of the species may be stopped in operation 562. In some embodiments, all flow of species is stopped and diverted in operation 562. In some embodiments, these steps may be performed by a controller that is operably connected with the valves and process chamber body. In other embodiments, the process of FIG. 5B may be performed automatically based on a pressure switch detecting a pressure beyond a threshold, where the pressure switch automatically causes one or more connected mixing vessel inlet valves to close.

In some embodiments, an anneal process may be performed following deposition of a silicon-containing film, where an example deposition process has been described in relation to FIG. 3. In some embodiments, the silicon-containing film deposition process may be performed using a low-pressure threshold, while the subsequent anneal process may be performed using a high-pressure threshold. An anneal process may comprise increasing the temperature of a heater in a pedestal to a temperature greater than, e.g., about 400° C., or about 500° C. In some embodiments, an inert gas may be flowed during the anneal process and optionally hydrogen- and/or oxygen-containing species may also be co-flowed during the anneal process. In some embodiments, a hazardous production material, such as silanes, are not flowed during the anneal process. In some embodiments, a pressure of the process chamber during the anneal process may be greater than about 30 Torr, about 40 Torr, or about 50 Torr, about 100 Torr, or between about 30 Torr and about 550 Torr. In some embodiments, the pressure of the process chamber during the anneal process is higher than a pressure of the process chamber during a deposition process to deposit a silicon-containing film.

### Apparatus

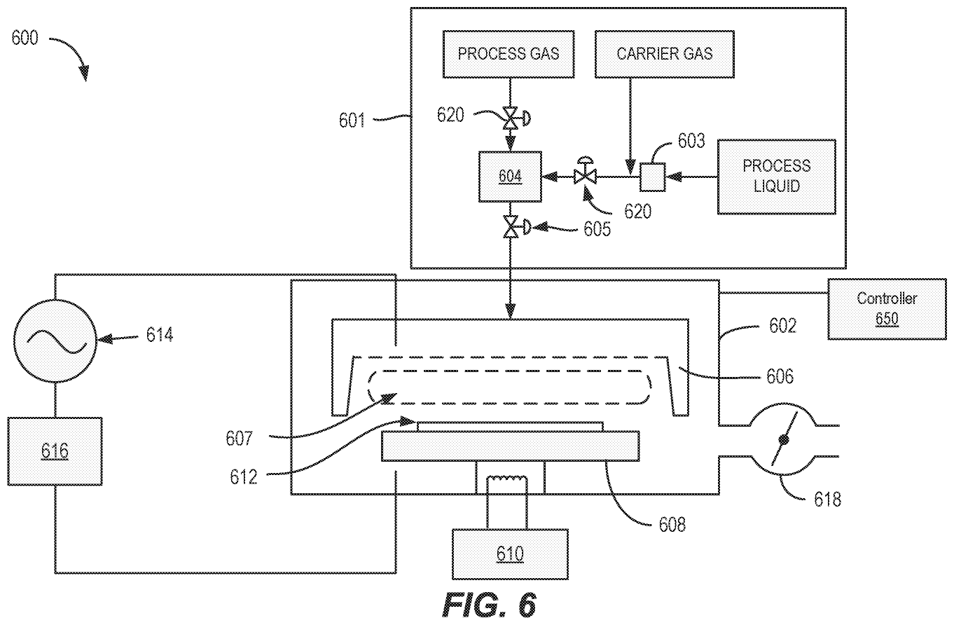

FIG. 6 schematically shows an embodiment of a process station 600 that may be used to deposit material using atomic layer deposition (ALD) and/or chemical vapor deposition (CVD), either of which may be plasma enhanced. For simplicity, the process station 600 is depicted as a standalone process station having a process chamber body 602 for maintaining a lower than atmospheric-pressure environment. However, it will be appreciated that a plurality of process stations 600 may be included in a common process tool environment. Further, it will be appreciated that, in some embodiments, one or more hardware parameters of process station 600, including those discussed in detail below, may be adjusted programmatically by one or more computer controllers 650.

Process station 600 fluidly communicates with reactant delivery system 601 for delivering process gases to a distribution showerhead 606. Reactant delivery system 601 includes a mixing vessel 604 for blending and/or conditioning process gases for delivery to distribution showerhead 606. One or more mixing vessel inlet valves 620 may control introduction of process gases to mixing vessel 604. Similarly, a showerhead inlet valve 605 may control introduction of process gasses to the distribution showerhead 606. In some embodiments, an inhibitor or other gas may be directly delivered to the process chamber body 602. One or more mixing vessel inlet valves 620 may control introduction of process gases to mixing vessel 604. These valves may be controlled depending on whether a process gas, inhibition gas, or carrier gas may be turned on during various operations. In some embodiments, an inhibition gas may be generated by using an inhibition liquid and vaporizing using a heated vaporizer. In some embodiments, reactant delivery system 601 may have pressure switches connected to the one or more mixing vessel inlet valves 620 as described above in reference to FIG. 5A.

As an example, the embodiment of FIG. 6 includes a vaporization point 603 for vaporizing liquid reactant to be supplied to mixing vessel 604. In some embodiments, vaporization point 603 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 603 may be heat traced. In some examples, mixing vessel 604 may also be heat traced. In one non-limiting example, piping downstream of vaporization point 603 has an increasing temperature profile extending from approximately 100° C., to approximately 150° C., at mixing vessel 604.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to distribution showerhead 606.

In some embodiments, a liquid flow controller (LFC) upstream of vaporization point 603 may be provided for controlling a mass flow of liquid for vaporization and delivery to process station 600. For example, the liquid flow controller may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Distribution showerhead 606 distributes process gases toward substrate 612. In the embodiment shown in FIG. 6, substrate 612 is located beneath distribution showerhead 606, and is shown resting on a pedestal 608. It will be appreciated that distribution showerhead 606 may have any suitable shape and may have any suitable number and arrangement of ports for distributing processes gases to substrate 612.

In some embodiments, a microvolume 607 is located beneath distribution showerhead 606. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 608 may be raised or lowered to expose substrate 612 to microvolume 607 and/or to vary a volume of microvolume 607. For example, in a substrate transfer phase, pedestal 608 may be lowered to allow substrate 612 to be loaded onto pedestal 608. During a deposition process phase, pedestal 608 may be raised to position substrate 612 within microvolume 607. In some embodiments, microvolume 607 may completely enclose substrate 612 as well as a portion of pedestal 608 to create a region of high flow impedance during a deposition process.

Optionally, pedestal 608 may be lowered and/or raised during portions the deposition process to modulate process pressure, reactant concentration, etc., within microvolume 607. In one scenario where process chamber body 602 remains at a base pressure during the deposition process, lowering pedestal 608 may allow microvolume 607 to be evacuated. Example ratios of microvolume to process chamber volume include, but are not limited to, volume ratios between 1:600 and 1:10. It will be appreciated that, in some embodiments, pedestal height may be adjusted programmatically by a suitable computer controller.

In another scenario, adjusting a height of pedestal 608 may allow a plasma density to be varied during plasma activation and/or treatment cycles included in the deposition process. At the conclusion of the deposition process phase, pedestal 608 may be lowered during another substrate transfer phase to allow removal of substrate 612 from pedestal 608.

While the example microvolume variations described herein refer to a height-adjustable pedestal, it will be appreciated that, in some embodiments, a position of distribution showerhead 606 may be adjusted relative to pedestal 608 to vary a volume of microvolume 607. Further, it will be appreciated that a vertical position of pedestal 608 and/or distribution showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers.

Returning to the embodiment shown in FIG. 6, distribution showerhead 606 and pedestal 608 electrically communicate with RF power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Examples of suitable powers are included above. Likewise, RF power supply 614 may provide RF power of any suitable frequency. In some embodiments, RF power supply 614 may be configured to control high- and low-frequency RF power sources independently of one another. Example low-frequency RF frequencies may include, but are not limited to, frequencies between 50 KHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 608 may be temperature controlled via heater 610. Further, in some embodiments, pressure control for process station 600 may be provided by butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to process station 600.

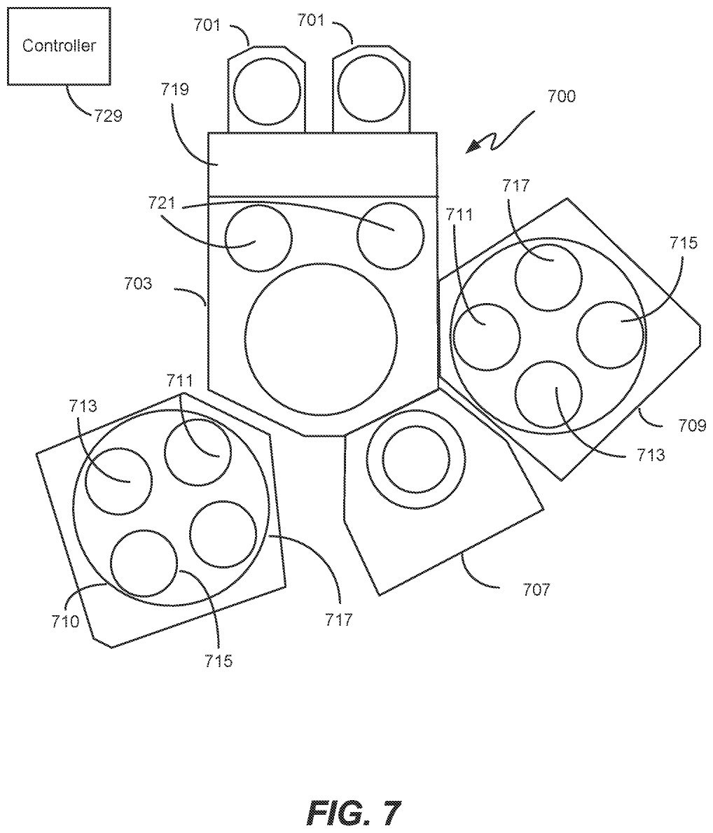

FIG. 7 is a block diagram of a processing system suitable for conducting thin film deposition processes in accordance with certain embodiments. The system 700 includes a transfer module 703. The transfer module 703 provides a clean, pressurized environment to minimize risk of contamination of substrates being processed as they are moved between various reactor modules. Mounted on the transfer module 703 are two multi-station reactors 709 and 710, each capable of performing atomic layer deposition (ALD) and/or chemical vapor deposition (CVD) according to certain embodiments. Reactors 709 and 710 may include multiple stations 711, 713, 715, and 717 that may sequentially or non-sequentially perform operations in accordance with disclosed embodiments. The stations may include a heated pedestal or substrate support, one or more gas inlets or showerhead or dispersion plate.

Also mounted on the transfer module 703 may be one or more single or multi-station modules 707 capable of performing plasma or chemical (non-plasma) pre-cleans, or any other processes described in relation to the disclosed methods. The module 707 may in some cases be used for various treatments to, for example, prepare a substrate for a deposition process. The module 707 may also be designed/configured to perform various other processes such as etching or polishing. The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all of the activities of the deposition apparatus. The system controller 729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 729 may be employed in some embodiments.

Typically there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 729. The signals for controlling the process are output on the analog and digital output connections of the system 700.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller, such as computer controller 650 or 729, is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 729, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

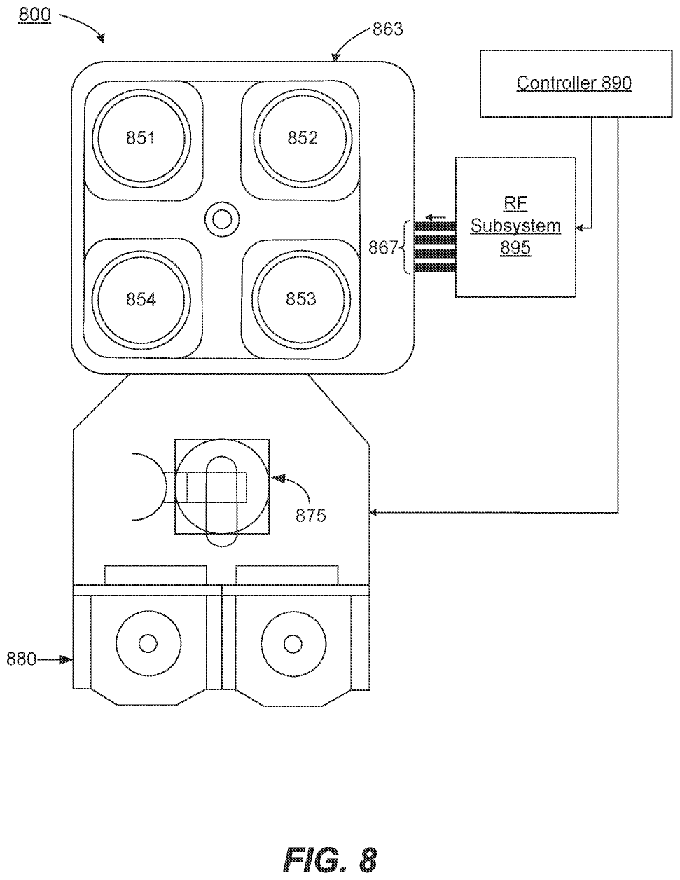

It may be appreciated that a plurality of process stations may be included in a multi-station processing tool environment, such as shown in FIG. 8, which depicts a schematic view of an embodiment of a multi-station processing tool. Processing apparatus 800 employs an integrated circuit fabrication chamber 863 that includes multiple fabrication process stations, each of which may be used to perform processing operations on a substrate held in a wafer holder, such as a pedestal, at a particular process station. In the embodiment of FIG. 8, the integrated circuit fabrication chamber 863 is shown having four process stations 851, 852, 853, and 854. Other similar multi-station processing apparatuses may have more or fewer process stations depending on the implementation and, for example, a desired level of parallel wafer processing, size/space constraints, cost constraints, etc. Also shown in FIG. 8 is substrate handler robot 875, which may operate under the control of system controller 890, configured to move substrates from a wafer cassette (not shown in FIG. 8) from loading port 880 and into integrated circuit fabrication chamber 863, and onto one of process stations 851, 852, 853, and 854.

FIG. 8 also depicts an embodiment of a system controller 890 employed to control process conditions and hardware states of processing apparatus 800. System controller 890 may include one or more memory devices, one or more mass storage devices, and one or more processors, as described herein.

RF subsystem 895 may generate and convey RF power to integrated circuit fabrication chamber 863 via radio frequency input ports 867. In particular embodiments, integrated circuit fabrication chamber 863 may comprise input ports in addition to radio frequency input ports 867 (additional input ports not shown in FIG. 8). Accordingly, integrated circuit fabrication chamber 863 may utilize 8 RF input ports. In particular embodiments, process stations 851-854 of integrated circuit fabrication chamber 165 may each utilize first and second input ports in which a first input port may convey a signal having a first frequency and in which a second input port may convey a signal having a second frequency. Use of dual frequencies may bring about enhanced plasma characteristics.

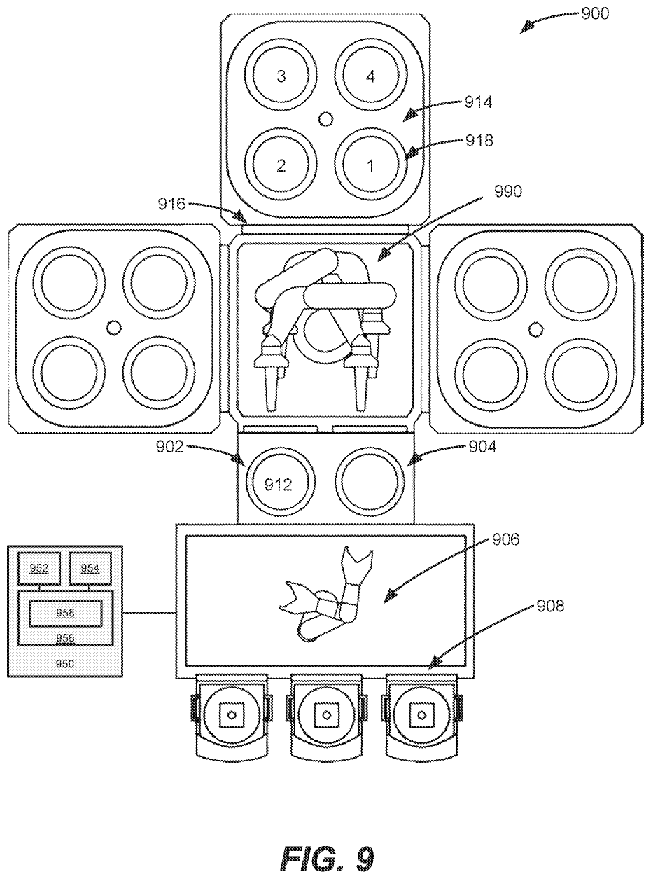

As described above, one or more process stations may be included in a multi-station processing tool. FIG. 9 shows a schematic view of an embodiment of a multi-station processing tool 900 with an inbound load lock 902 and an outbound load lock 904, either or both of which may comprise a remote plasma source. A robot 906, at atmospheric pressure, is configured to move substrates or wafers from a cassette loaded through a pod 908 into inbound load lock 902 via an atmospheric port. A substrate is placed by the robot 906 on a pedestal 912 in the inbound load lock 902, the atmospheric port is closed, and the load lock is pumped down. Where the inbound load lock 902 comprises a remote plasma source, the substrate may be exposed to a remote plasma treatment in the load lock prior to being introduced into a processing chamber 914. Further, the substrate also may be heated in the inbound load lock 902 as well, for example, to remove moisture and adsorbed gases. Next, a chamber transport port 916 to processing chamber 914 is opened, and a wafer handling system 990 places the substrate into the reactor on a pedestal of a first station shown in the reactor for processing. While the embodiment depicted in FIG. 9 includes load locks, it will be appreciated that, in some embodiments, direct entry of a substrate into a process station may be provided. In various embodiments, the soak gas is introduced to the station when the substrate is placed by the robot 906 on the pedestal 912.

The depicted processing chamber 914 comprises four process stations, numbered from 1 to 4 in the embodiment shown in FIG. 9. Each station has a heated pedestal (shown at 918 for station 1), and gas line inlets. It will be appreciated that in some embodiments, each process station may have different or multiple purposes. For example, in some embodiments, a process station may be switchable between an ALD and PEALD process mode. Additionally or alternatively, in some embodiments, processing chamber 914 may include one or more matched pairs of ALD and plasma-enhanced ALD process stations. While the depicted processing chamber 914 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 9 depicts an embodiment of a wafer handling system 990 for transferring substrates within processing chamber 914. In some embodiments, wafer handling system 990 may transfer substrates between various process stations and/or between a process station and a load lock. It will be appreciated that any suitable wafer handling system may be employed. Non-limiting examples include wafer carousels and wafer handling robots. FIG. 9 also depicts an embodiment of a system controller 950 employed to control process conditions and hardware states of process tool 900. System controller 950 may include one or more memory devices 956, one or more mass storage devices 954, and one or more processors 952. Processor 952 may include a CPU or computer, analog and/or digital input/output connections, stepper motor controller boards, etc. In some embodiments, system controller 950 includes machine-readable instructions for performing operations such as those described herein.

In some embodiments, system controller 950 controls the activities of process tool 900. System controller 950 executes system control software 958 stored in mass storage device 954, loaded into memory device 956, and executed on processor 952. Alternatively, the control logic may be hard coded in the system controller 950. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 958 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 900. System control software 958 may be configured in any suitable way. For example, various process tool component subroutines or control objects may be written to control operation of the process tool components used to carry out various process tool processes. System control software 958 may be coded in any suitable computer readable programming language.

### Conclusion

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method, comprising:
providing a substrate having a structure with a gap in a process chamber; and
performing a first set of one or more cycles of:
(a) exposing the substrate to a plasma comprising an inhibition gas to inhibit deposition on a portion of the gap; and
(b) after (a), depositing dielectric material in the gap; and
after performing the first set of one or more cycles, depositing additional dielectric material in the gap, wherein a pressure of the process chamber is at least 8 Torr during (a) and (b).

2. The method of claim 1, wherein the pressure of the process chamber is between about 8 Torr and about 30 Torr during (a) and (b).

3. The method of claim 1, wherein the pressure of the process chamber is between about 8 Torr and about 100 Torr during (a) and (b).

4. The method of claim 1, wherein the pressure of the process chamber during (b) is different from the pressure of the process chamber during (a).

5. The method of claim 1, wherein the pressure of the process chamber during (b) is the same as the pressure of the process chamber during (a).

6. The method of claim 1, wherein depositing dielectric material during (b) is performed using an atomic layer deposition (ALD) process.

7. The method of claim 6, wherein the ALD process is a plasma enhanced ALD process.

8. The method of claim 1, further comprising, before (a), depositing a conformal liner film in the gap using an ALD process.

9. The method of claim 1, wherein the inhibition gas is a halogen-containing gas.

10. The method of claim 1, wherein the inhibition gas is a nitrogen-containing gas.

11. The method of claim 1, wherein a temperature of the process chamber is between about 200° C., and about 800° C., during (a) and (b).

12. The method of claim 1, wherein the plasma has a high-frequency component power between about 250 W and about 1500 W per substrate.

13. The method of claim 1, wherein the plasma has a low-frequency component power between about 250 W and about 1250 W per substrate.

14. The method of claim 1, wherein the dielectric material is silicon-containing material.

15. The method of claim 1, wherein the dielectric material is silicon oxide.

16. A system, comprising:
a process chamber;
a first valve that controls flow of a first process gas into the process chamber;
a second valve that controls flow of a second process gas into the process chamber;
a controller configured to:
determine a pressure of the process chamber exceeds a first threshold; and
cause the first valve to divert flow of the first process gas to not flow into the process chamber, wherein the second valve remains configured to flow the second process gas into the process chamber.

17. The system of claim 16, further comprising a first pressure switch, wherein the first pressure switch is configured to automatically divert the first process gas when the process chamber exceeds the first threshold.

18. The system of claim 17, further comprising a second pressure switch, wherein the second pressure switch is configured to automatically divert the second process gas when the process chamber exceeds a second threshold, wherein the second threshold is higher than the first threshold.

19. The system of claim 16, wherein the first threshold is about 30 Torr.

20. The system of claim 16, wherein the controller is further configured to determine a pressure of the process chamber exceeds a second threshold higher than the first threshold and, based on the determination that the pressure exceeds the second threshold, cause the second valve to divert flow of the second process gas to not flow into the process chamber.

21. The system of claim 20, wherein the second threshold is about 550 Torr.

22. The system of claim 16, wherein the first process gas comprises a hazardous production material.

23. The system of claim 16, wherein the first process gas comprises a silicon-containing precursor.

24. The system of claim 16, wherein the second process gas comprises an inert gas.
